(19) United States
(12) Patent Application Publication
(10) Pub. No.: US 2026/0190915 A1
(43) Pub. Date: Jul. 2, 2026

(54) SUBSTRATE PROCESSING APPARATUS AND SUBSTRATE PROCESSING METHOD

(71) Applicant: SEMES CO., LTD., Cheonan-si (KR)

(72) Inventors: Gu Won SEON, Seoul (KR); Koriakin ANTON, Suwon-si (KR); Joon Ho WON, Suwon-si (KR)

(73) Assignee: SEMES CO., LTD., Cheonan-si (KR)

(21) Appl. No.: 19/426,870

(22) Filed: Dec. 19, 2025

(30) Foreign Application Priority Data
Dec. 26, 2024 (KR) 10-2024-0197626

(51) Int. Cl. H10P 72/00

(52) U.S. Cl. CPC H10P 72/0448; H10P 72/0604

(57) ABSTRACT

Provided is an apparatus for processing a substrate. The apparatus includes: a treating unit for processing a substrate; and a liquid supply unit for supplying a treatment liquid to the substrate disposed in the treating unit, in which the liquid supply unit includes: a bottle for storing the treatment liquid; a liquid supply line for supplying the treatment liquid from the bottle to the treating unit; a trap tank installed in the liquid supply line and temporarily storing the treatment liquid; a negative pressure forming unit for forming a negative pressure inside the trap tank to feed the treatment liquid in the bottle to the trap tank; a cleaning liquid supply unit for supplying a cleaning liquid to the negative pressure forming unit; and a sampling unit for detecting the amount of the treatment liquid introduced into the negative pressure forming unit.

### CROSS-REFERENCE TO RELATED APPLICATION

This application claims priority to and the benefit of Korean Patent Application No. 10-2024-0197626 filed in the Korean Intellectual Property Office on Dec. 26, 2024, the entire contents of which are incorporated herein by reference.

### TECHNICAL FIELD

The present invention relates to an apparatus and a method of processing a substrate, and more specifically, to an apparatus and a method of liquid-treating a substrate with a liquid by supplying the liquid in a bottle to a substrate.

### BACKGROUND ART

In order to manufacture a semiconductor device, various processes, such as cleaning, deposition, photography, etching, and ion implantation, are performed. Among the processes, the photography process includes a coating process of forming a film by coating a surface of the substrate with a photosensitive liquid, such as photoresist, an exposure process that transfers a circuit pattern to a film formed on the substrate, and a developing process that selectively removes a film formed on the substrate in a region on which the exposure process has been performed or a region opposite to the region.

Typically, a device that performs a coating process supplies a liquid, such as photoresist, from a nozzle to a rotating substrate to form a liquid film on the substrate. FIG. 1 is a diagram schematically illustrating a structure of a general liquid supply unit for supplying a photoresist to a nozzle. Referring to FIG. 1, the liquid supply unit 9000 stores a photoresist in a bottle 9100 in a trap tank 9500, and then supplies the photoresist in the trap tank 9500 to the nozzle 9700.

A gas supply pipe 9310 is connected to the bottle 9100, and the gas supply unit 9300 supplies high-pressure gas into the bottle 9100 through the gas supply pipe 9310. In general, gas is supplied so that the pressure in the bottle 9100 is raised to several tens of kPa in order to feed the photoresist in the bottle 9100 into the trap tank 9500 by the gas pressure.

However, the high gas pressure increases the amount of gas dissolved in the photoresist stored in the bottle 9100, and a large amount of air bubbles are generated in the photoresist when the photoresist flows along the supply pipes 9910 and 9930 or is applied over the substrate W. As a result, the amount of photoresist smaller than the set amount is applied to the substrate W, and this affects the thickness of the applied liquid film to occur a defect in air volume.

### SUMMARY OF THE INVENTION

The present invention has been made in an effort to provide a substrate processing apparatus and a substrate processing method capable of improving substrate processing efficiency.

The present invention has also been made in an effort to provide a substrate processing apparatus and a substrate processing method capable of preventing a large amount of air bubbles from being generated in a liquid supplied to a substrate.

The present invention has been made in an effort to provide a substrate processing apparatus and a substrate processing method capable of efficiently cleaning an ejector into which a liquid is introduced.

Effects of the present disclosure are not limited to those described above and effects not stated above will be clearly understood to those skilled in the art from the specification and the accompanying drawings.

An exemplary embodiment of the present disclosure, an apparatus for processing a substrate, the apparatus comprising: a treating unit for processing a substrate; and a liquid supply unit for supplying a treatment liquid to the substrate disposed in the treating unit, wherein the liquid supply unit includes: a bottle for storing the treatment liquid; a liquid supply line for supplying the treatment liquid from the bottle to the treating unit; a trap tank installed in the liquid supply line and temporarily storing the treatment liquid; a negative pressure forming unit for forming a negative pressure inside the trap tank to feed the treatment liquid in the bottle to the trap tank; a cleaning liquid supply unit for supplying a cleaning liquid to the negative pressure forming unit; and a sampling unit for detecting the amount of the treatment liquid introduced into the negative pressure forming unit.

According to the exemplary embodiment of the present invention, wherein the negative pressure forming unit includes: an ejector; an inlet pipe for supplying gas to the ejector; an outlet pipe for discharging the gas that has passed through the ejector; and a suction pipe connecting the ejector and the trap tank, and the sampling unit may includes: a sampling pipe branched from the outlet pipe; and a sampling device for detecting the amount of the treatment liquid introduced through the sampling pipe.

According to the exemplary embodiment of the present invention, wherein the cleaning liquid supply unit may include a cleaning liquid supply pipe connected to the suction pipe.

According to the exemplary embodiment of the present invention, wherein the sampling device may be an ultraviolet-visible spectrophotometer (UV-Vis spectrophotometer).

According to the exemplary embodiment of the present invention, wherein a first opening/closing valve is installed in the outlet pipe, and a point at which the sampling pipe is branched from the outlet pipe may be located between the ejector and the first opening/closing valve.

According to the exemplary embodiment of the present invention, wherein a second opening/closing valve is installed in the inlet pipe, a third opening/closing valve is installed in the sampling pipe, a fourth opening/closing valve is installed in the suction pipe, a fifth opening/closing valve is installed in the cleaning liquid supply pipe, and the cleaning liquid supply pipe may be connected to the suction pipe between the ejector and the fourth opening/closing valve.

According to the exemplary embodiment of the present invention, further comprising: controller for controlling the liquid supply unit, wherein a sensor for detecting whether the treatment liquid is introduced is further installed in the outlet pipe, and when the sensor detects that the treatment liquid has been introduced into the outlet pipe, the controller may controls the liquid supply unit to close the first opening/closing valve, the second opening/closing valve, and the fourth opening/closing valve, and open the third opening/closing valve and the fifth opening/closing valve.

According to the exemplary embodiment of the present invention, further comprising: controller for controlling the liquid supply unit, wherein the controller may determines the amount of cleaning liquid supplied to the negative pressure forming unit according to the amount of the treatment liquid detected by the sampling unit.

According to the exemplary embodiment of the present invention, wherein the controller detects the amount of the treatment liquid remaining in the negative pressure forming unit through the sampling unit again after the cleaning liquid is supplied to the negative pressure forming unit, and feedback-controls the sampling unit and the cleaning liquid supply unit to supply the cleaning liquid to the negative pressure forming unit until the amount of the treatment liquid detected by the sampling unit becomes less than or equal to a set amount.

According to the exemplary embodiment of the present invention, wherein the treatment liquid may be a photoresist.

According to the exemplary embodiment of the present invention, wherein the cleaning liquid may be a thinner.

An exemplary embodiment of the present disclosure, a method of processing a substrate, the method comprising: forming a negative pressure inside a trap tank through a negative pressure forming unit to feed a treatment liquid in a bottle to the trap tank; and supplying the treatment liquid temporarily stored in the trap tank to a substrate disposed in a treating unit to process the substrate, wherein when the treatment liquid in the trap tank is introduced into the negative pressure forming unit, the amount of the treatment liquid introduced into the negative pressure forming unit is detected through a sampling unit, and a cleaning liquid whose supply amount is determined according to the amount of the treatment liquid detected by the sampling unit may be supplied to the negative pressure forming unit.

According to the exemplary embodiment of the present invention, wherein after the cleaning liquid is supplied to the negative pressure forming unit, the amount of the treatment liquid remaining in the negative pressure forming unit is detected through the sampling unit again, and the cleaning liquid may be supplied to the negative pressure forming unit until the amount of the treatment liquid detected by the sampling unit is less than a set amount.

According to the exemplary embodiment of the present invention, wherein when the treatment liquid in the trap tank is introduced into the negative pressure forming unit, the negative pressure forming unit stops forming a negative pressure and then the cleaning liquid is supplied to the negative pressure forming unit, and when the amount of the treatment liquid detected by the sampling unit becomes less than the set amount, the supply of the cleaning liquid to the negative pressure forming unit may be stopped.

According to the exemplary embodiment of the present invention, wherein the sampling unit may detects the amount of the treatment liquid introduced into the negative pressure forming unit through an ultraviolet-visible spectroscopy (UV-Vis spectroscopy).

According to the exemplary embodiment of the present invention, wherein the negative pressure forming unit includes: an ejector; an inlet pipe for supplying gas to the ejector; an outlet pipe for discharging the gas that has passed through the ejector; and a suction pipe connecting the ejector and the trap tank, and when the treatment liquid in the trap tank is introduced into the negative pressure forming unit, the negative pressure forming unit may close the inlet pipe and the outlet pipe.

According to the exemplary embodiment of the present invention, wherein the treatment liquid may be a photoresist.

According to the exemplary embodiment of the present invention, wherein the cleaning liquid may be a thinner.

An exemplary embodiment of the present disclosure, a method of processing a substrate, the method comprising: forming a negative pressure inside a trap tank through a negative pressure forming unit to feed a photoresist in a bottle to the trap tank; and supplying the photoresist temporarily stored in the trap tank to the substrate disposed in the treating unit to process the substrate, wherein when the photoresist in the trap tank is introduced into the negative pressure forming unit, the negative pressure forming unit stops forming a negative pressure, the amount of the photoresist introduced into the negative pressure forming unit is detected through a sampling unit, a thinner whose supply amount is determined according to the amount of the photoresist detected by the sampling unit is supplied to the negative pressure forming unit, after the thinner is supplied to the negative pressure forming unit, the amount of photoresist remaining in the negative pressure forming unit is detected through the sampling unit again, and the thinner is supplied to the negative pressure forming unit until the amount of the photoresist detected by the sampling unit is less than a set amount, and when the amount of the photoresist detected by the sampling unit becomes less than the set amount, the supply of the thinner to the negative pressure forming unit may be stopped.

According to the exemplary embodiment of the present invention, wherein the negative pressure forming unit includes: an ejector; an inlet pipe for supplying gas to the ejector; an outlet pipe for discharging the gas that has passed through the ejector; and a suction pipe connecting the ejector and the trap tank, and when the photoresist in the trap tank is introduced into the negative pressure forming unit, the negative pressure forming unit may close the inlet pipe and the outlet pipe.

According to the exemplary embodiment of the present invention, it is possible to improve substrate processing efficiency.

According to the exemplary embodiment of the present invention, it is possible to prevent a large amount of air bubbles from being generated in a liquid supplied to a substrate.

According to the exemplary embodiment of the present invention, it is possible to efficiently clean an ejector into which a liquid is introduced.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram schematically illustrating a structure of a general liquid supply unit for supplying a photoresist to a nozzle.

FIG. 2 is a diagram schematically illustrating a substrate processing apparatus according to an exemplary embodiment of the present invention.

FIG. 3 is a diagram schematically illustrating one example of the liquid treating chamber of FIG. 2.

FIG. 4 is a diagram schematically illustrating an example of a negative pressure forming unit of FIG. 2.

FIGS. 5 to 7 are diagrams schematically illustrating an exemplary embodiment of a process of supplying a liquid when a photoresist is not introduced into an ejector.

FIGS. 8 to 9 are diagrams schematically illustrating an exemplary embodiment of a process of supplying a liquid when a photoresist is introduced into the ejector.

FIG. 10 is a flowchart illustrating a method of cleaning the ejector after the photoresist is introduced into the ejector.

FIG. 11 is a diagram schematically illustrating another exemplary embodiment of the substrate processing apparatus of FIG. 2.

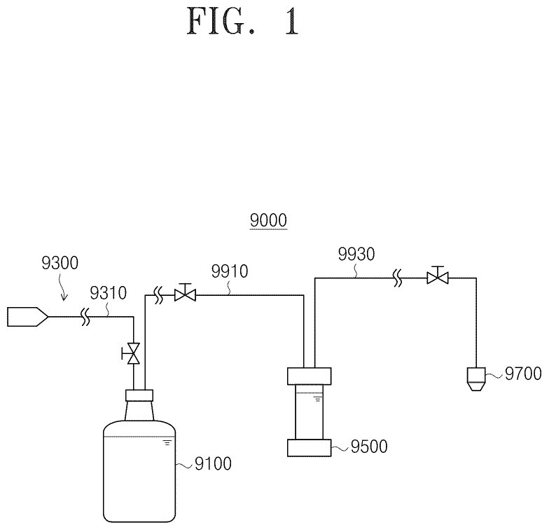

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜and ˜”, “just between ˜and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

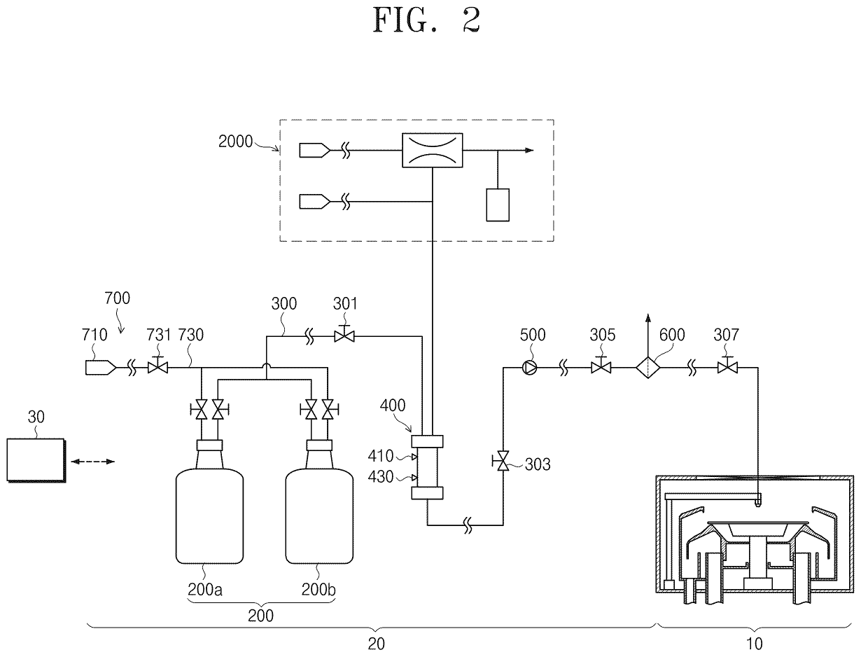

Hereinafter, an exemplary embodiment of the present invention will be described with reference to FIGS. 2 to 11.

In the following exemplary embodiment, the case where a substrate processing apparatus is an apparatus for performing a coating process of coating a photoresist on a substrate will be described as an example. However, unlike this, the substrate processing apparatus may be an apparatus for coating an antireflection film, a protective film, or another kind of liquid onto a substrate.

FIG. 2 is a diagram schematically illustrating a substrate processing apparatus according to an exemplary embodiment of the present invention. Referring to FIG. 2, a substrate processing apparatus 1 includes a liquid treating chamber 10, a liquid supply unit 20, and a controller 30. The liquid treating chamber 10 applies a photoresist film to a substrate W loaded into an inside thereof. The liquid supply unit 20 supplies a photoresist to the liquid treating chamber 10. The controller 30 controls the liquid treating chamber 10 and the liquid supply unit 20.

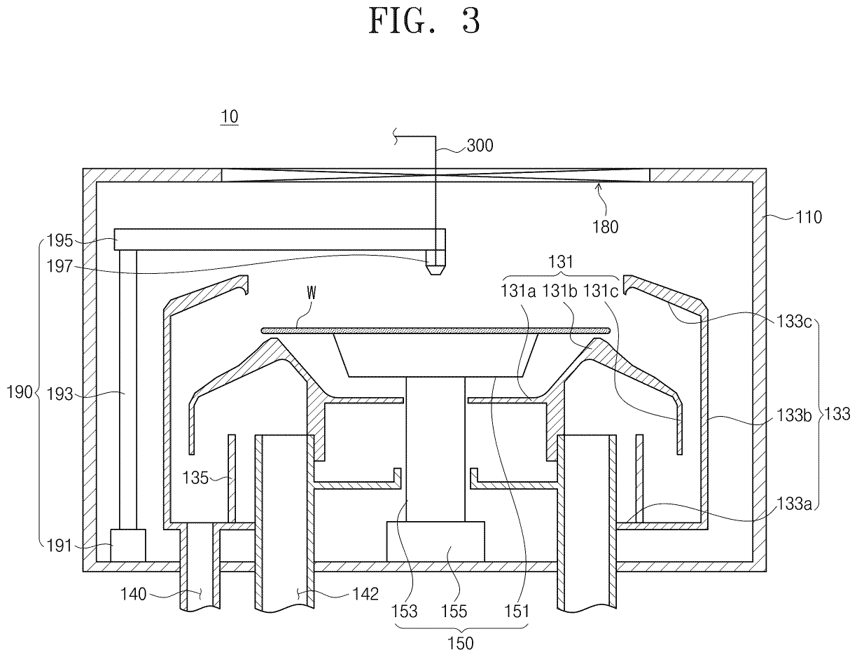

FIG. 3 is a diagram schematically illustrating an exemplary embodiment of the liquid treating chamber of FIG. 2. Referring to FIG. 2, the liquid treating chamber 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the inner space or the substrate W is unloaded from the inner space. Also, a door (not illustrated) is installed in an area adjacent to the entrance to selectively open and close the entrance. A door (not illustrated) blocks the entrance and seals the inner space from the outside while the processing process is performed on the substrate W loaded into the inner space. The cup 133, the support unit 150, the guide ring 131, and the nozzle unit 190 may be disposed in the inner space of the housing 110.

The cup 133 may be provided to surround the support unit 150 and the guide ring 131. The cup 133 may include a bottom wall 133a, a sidewall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

A gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the sidewall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate W is seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the inner space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the inner space of the housing 110. The support rod 193 is located on one side of a processing container 420 in the inner space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies photoresist to the nozzle 197 provided in the liquid treating chamber 10.

Referring back to FIG. 2, the liquid supply unit 20 includes a bottle 200, a liquid supply pipe 300, a trap tank 400, a pump 500, a filter 600, a gas supply unit 700, and a negative pressure forming unit 2000.

The bottle 200 has a storage space for storing photoresists. A plurality of bottles 200 may be provided. For example, the bottle 200 may include a first bottle 200a and a second bottle 200b. Accordingly, first, a photoresist is supplied from the first bottle 200a to the trap tank 400. When the photoresist is exhausted from the first bottle 200a, the photoresist is supplied from the second bottle 200b to the trap tank 400. While the photoresist is supplied from the second bottle 200b, the first bottle 200a from which the photoresist is exhausted is replaced with a new bottle filled with the photoresist. The first bottle 200a and the second bottle 200b have the same or similar structure.

The liquid supply pipe 300 supplies the photoresist in the bottle 200 to the liquid treating chamber 10. The liquid supply pipe 300 is provided with a flow path through which a photoresist may flow. A trap tank 400, a pump 500, and a filter 600 are installed in the liquid supply pipe 300. The trap tank 400, the pump 500, and the filter 600 are sequentially disposed in a direction from the upstream to the downstream.

Opening/closing valves 301, 303, 305, and 307 for opening/closing an internal flow path of the liquid supply pipe 300 may be installed in the liquid supply pipe 300 between the bottle 200 and the trap tank 400, between the trap tank 400 and the pump 500, between the pump 500 and the filter 600, and between the filter 600 and the nozzle 197.

The photoresist stored in the bottle 200 is supplied to the trap tank 400. The trap tank 400 has an internal space for temporarily storing the photoresist. Water level detection sensors 410 and 430 are installed in the trap tank 400. The water level detection sensors 410 and 430 detect the water level of the photoresist stored in the inner space of the trap tank 400. A plurality of water level detection sensors 410 and 430 may be provided. According to an example, the water level detection sensors 410 and 430 may include a first water level detection sensor 410 and a second water level detection sensor 430 positioned lower than the first water level detection sensor 410.

The pump 500 provides a flow pressure for flowing a photoresist temporarily stored in the trap tank 400 into the liquid treating chamber 10. The pump 500 is installed in the liquid supply pipe 300 on the downstream side of the trap tank 400.

The filter 600 filters impurities inside the photoresist supplied to the nozzle 197. The filtered impurities are drained from the filter 600 and discharged to the outside. The filter 600 is installed in the liquid supply pipe 300 at the downstream side of the pump 500.

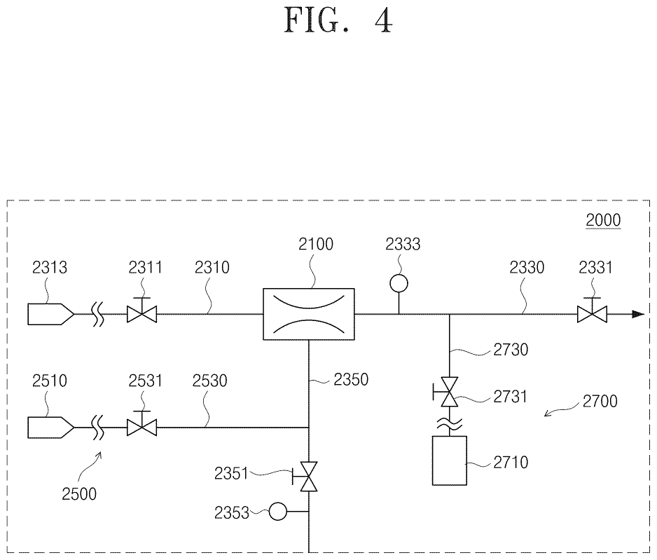

The negative pressure forming unit 2000 is connected to the trap tank 400 to form a negative pressure in the inner space of the trap tank 400. FIG. 4 is a diagram schematically illustrating an example of the negative pressure forming unit 200 of FIG. 2.

Referring to FIG. 4, the negative pressure forming unit 2000 includes an ejector 2100, an inlet pipe 2310, an outlet pipe 2330, a suction pipe 2350, a cleaning liquid supply unit 2500, and a sampling unit 2700.

The inlet pipe 2310 and the outlet pipe 2330 are connected to opposite ends of the ejector 2100, respectively, and the suction pipe 2350 is connected to a lower end of the ejector 2100. The inlet pipe 2310 is connected to the gas supply source 2313 so as to flow gas supplied from the gas supply source 2313 to the ejector 2100. The gas introduced into the ejector 2100 may be discharged to the outside through the outlet pipe 2330. An inlet pipe valve 2311 for opening and closing the internal flow path of the inlet pipe 2310 is provided in the inlet pipe 2310, and an outlet pipe valve 2331 for opening and closing the internal flow path of the outlet pipe 2330 is provided in the outlet pipe 2330.

The suction pipe 2350 connects the ejector 2100 to the inner space of the trap tank 400. The suction pipe 2350 may be provided with a suction pipe valve 2351 that opens and closes the internal flow path thereof.

Due to the change in the inner passage area of the ejector 2100, the speed of the gas passing through the ejector 2100 becomes faster than the speed before and after passing, and negative pressure is formed in the ejector 2100. Accordingly, as the gas inside the trap tank 400 flows to the ejector 2100 and the outlet pipe 2150 through the suction pipe, negative pressure is formed in the inner space of the trap tank 400.

A first sensor 2353, a second sensor 2333, a cleaning liquid supply unit 2500, and a sampling unit 2700 are provided in the negative pressure forming unit 2000 to prevent the photoresist temporarily stored inside the trap tank 400 from flowing into the ejector 2100 by the negative pressure formed by the ejector 2100, and remove the introduced photoresist when the photoresist in the trap tank 400 is introduced into the injector 2100.

The first sensor 2353 is installed in the suction pipe 2350. The first sensor 2353 detects whether a photoresist is introduced into the suction pipe 2350. The first sensor 2353 may be an optical sensor. The first sensor 2353 is installed in the suction pipe 2350 between the suction pipe valve 2351 and the trap tank 400. When the first sensor 2353 detects the introduction of the photoresist into the suction pipe 2350, the controller 30 closes the suction pipe valve 2351 to prevent the photoresist from flowing into the ejector 2100.

The second sensor 2333 is installed in the outlet pipe 2330. The second sensor 2333 detects whether a photoresist is introduced into the ejector 2100. The second sensor 2333 may be an optical sensor. The second sensor 2333 is installed in the outlet pipe 2330 between the ejector 2100 and the outlet pipe valve 2331. When the second sensor 2333 detects the introduction of the photoresist into the ejector 2100, the controller 30 closes the inlet pipe valve 2311, the outlet pipe valve 2333, and the suction pipe valve 2351 and supplies a cleaning liquid to the ejector 2100 through the cleaning liquid supply unit 2500 to be described later to remove the photoresist introduced into the ejector 2100.

The cleaning liquid supply unit 2500 cleans the ejector 2100 into which the photoresist is introduced. As the cleaning liquid, a liquid for removing the photoresist remaining in the ejector 2100 is used. For example, the cleaning liquid may be a thinner. The cleaning liquid supply unit 2500 includes a cleaning liquid supply source 2510 and a cleaning liquid supply pipe 2530. The cleaning liquid supply pipe 2530 is provided with a cleaning liquid supply pipe valve 2531 for opening and closing the internal flow path thereof. According to an example, the cleaning liquid supply pipe valve 2531 may have a flow rate adjusting function of adjusting a flow rate of the cleaning liquid supplied to the ejector 2100. The cleaning liquid supply pipe 2530 may be connected to the suction pipe 2350 to supply the cleaning liquid to the suction pipe 2350. The cleaning liquid supply pipe 2530 may be connected to the suction pipe 2350 between the ejector 2100 and the suction pipe valve 2351.

The sampling unit 2700 detects the amount of photoresist introduced into the ejector 2100. The sampling unit 2700 includes a sampling device 2710 and a sampling pipe 2730. The sampling pipe 2730 may flow the photoresist branched from the outlet pipe 2330 and introduced into the ejector 2100 to the sampling device 2710. A point where the sampling pipe 2730 branches from the outlet pipe 2330 is located between the ejector 2100 and the outlet pipe valve 2331.

The sampling device 2710 measures the amount of photoresist introduced into the ejector 2100. The sampling device 2710 may be an ultraviolet-visible light spectrophotometer (UV-Vis spectrophotometer) that detects the amount of photoresist through ultraviolet-vis spectroscopy. Here, the UV-Vis spectrophotometer refers to a device that detects not only a liquid capable of absorbing ultraviolet rays and visible rays having a wavelength of about 200 nm to about 800 nm, but also a liquid capable of absorbing extreme ultraviolet rays having a wavelength of about 10 nm to about 200 nm. Accordingly, the sampling device 2710 may be used in various types of photoresist processes including EUV photoresist, ArF photoresist, and KrF photoresist.

The sampling device 2710 transmits information on the amount of detected photoresist to the controller 30. The controller 30 determines the amount of cleaning liquid supplied to the ejector 2100 according to the amount of photoresist measured by the sampling device 2710. According to an example, the amount of photoresist measured by the sampling device 2710 and the amount of cleaning liquid supplied to the ejector 2100 may be directly proportional.

Referring back to FIG. 2, the gas supply unit 700 supplies gas to the storage space of the bottle 200. The gas supply unit 700 includes a gas supply source 710 and a gas supply pipe 730.

Gas is stored in the gas supply source 710. The gas may be inert gas. According to an example, the gas may be nitrogen gas (N₂). The gas supply pipe 730 is connected to the gas supply source 710 and the bottle 200 to supply gas to the storage space of the bottle 200. An opening/closing valve 731 for opening and closing an internal flow path thereof is installed in the gas supply pipe 730.

The gas supply unit 700 fills the empty space inside the bottle 200 with gas when the photoresist stored in the bottle 200 is fed into the trap tank 400. Accordingly, outside air may be prevented from flowing into the bottle 200 and contaminating the photoresist. In addition, deformation of the bottle 200 may be prevented by maintaining the internal pressure of the bottle 200 above a certain pressure while the liquid is supplied from the bottle 200 to the trap tank 400.

Since negative pressure is formed in the inner space of the trap tank 400 by the negative pressure forming unit 2000, and the gas supply unit 700 micro-presses the photoresist stored in the bottle 200, the photoresist may be stably fed from the bottle 200 to the trap tank 400. According to an example, the gas supply unit 700 may supply gas so that the pressure of the gas in the bottle 200 is higher than normal pressure and at the same time a pressure lower than a pressure that is 5 kPa higher than normal pressure.

Since the amount of gas supplied into the bottle 200 is small, a large amount of gas is prevented from being dissolved in the photoresist transmitted from the bottle 200. Therefore, it is possible to prevent a large amount of air bubbles from being generated in the photoresist when the photoresist moves through the liquid supply pipe 300.

The controller 30 may control the liquid supply unit 20 and the substrate processing apparatus 1 including the same so as to perform a substrate processing method described below.

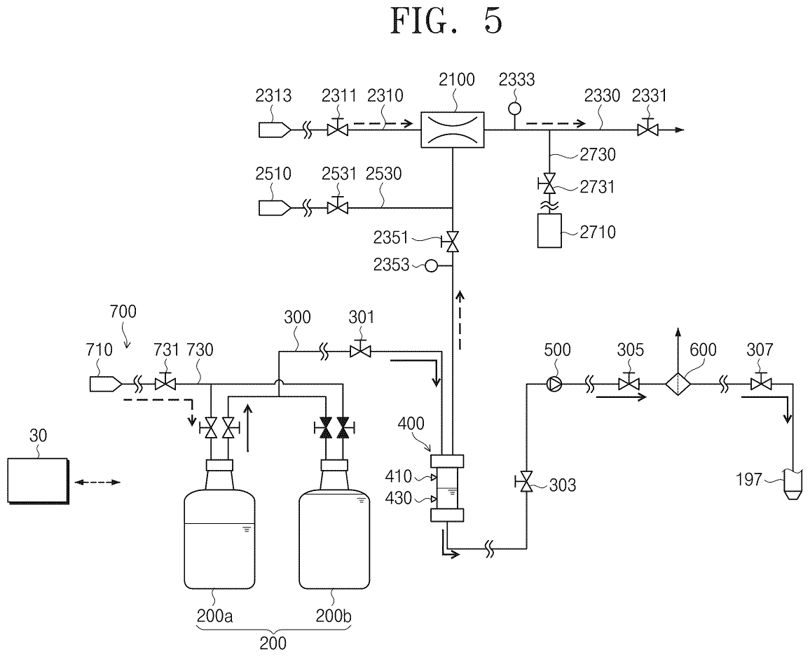

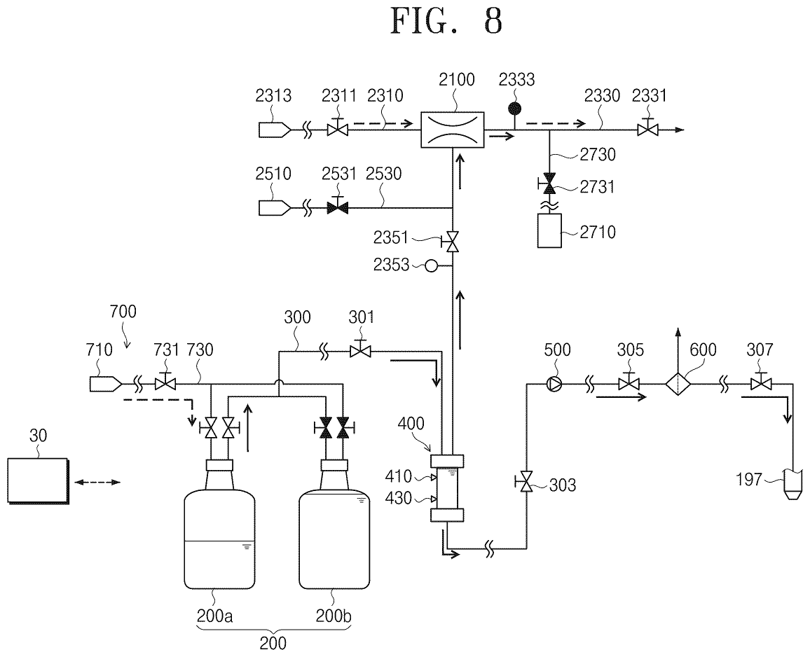

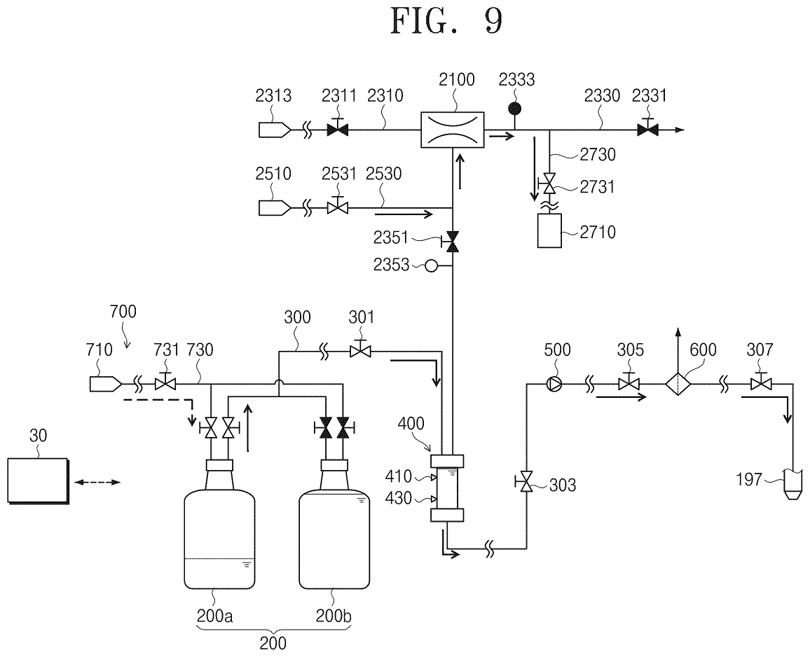

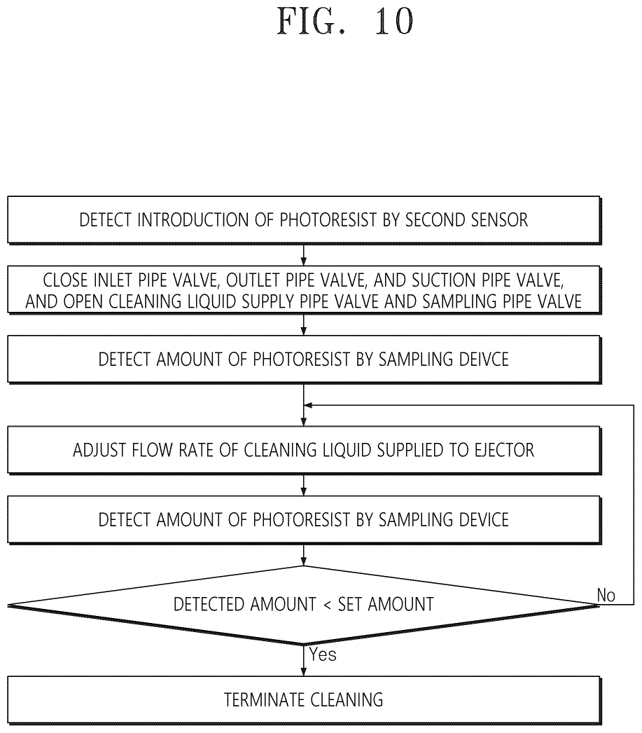

FIGS. 5 to 7 are diagrams schematically illustrating an exemplary embodiment of a process of supplying a liquid when a photoresist is not introduced into an ejector. FIGS. 8 to 9 are diagrams schematically illustrating an exemplary embodiment of a process of supplying a liquid when a photoresist is introduced into the ejector. FIG. 10 is a flowchart illustrating a method of cleaning the ejector after the photoresist is introduced into the ejector. In FIGS. 5 to 9, the valve with the filled inside is in a closed state for preventing the fluid from flowing, and the valve with an empty inside is in an open state for allowing the fluid to flow. The solid line arrow means the flow direction of the photoresist or cleaning liquid, and the dotted arrow means the flow direction of the gas. In addition, the first and second sensors 2353 and 2333 with the filled inside means a state in which the flow of the photoresist is detected, and the first and second sensors 2353 and 2333 with the filled inside means a state in which the flow of the photoresist is not detected.

Referring to FIG. 5, the gas supply unit 700 supplies gas to the bottle 200 to provide gas pressure to the bottle 200, and the negative pressure forming unit 2000 supplies gas to the ejector 2100 to form a negative pressure in the inner space of the trap tank 400. Accordingly, the photoresist stored in the bottle 200 is fed to the trap tank 400 to be filled in the inner space of the trap tank 400. The photoresist temporarily stored in the trap tank 400 is supplied to the nozzle 197 through the pump 500 and the filter 600 by the flow pressure of the pump 500.

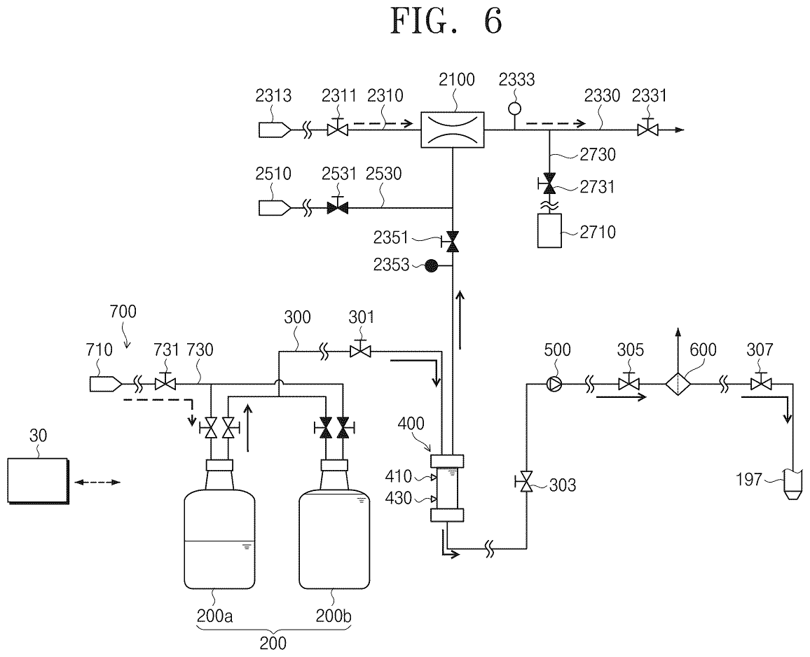

When the photoresist supplied from the bottle 200 is filled in the inner space of the trap tank 400 at a predetermined level or more, a part of the photoresist in the trap tank 400 is introduced into the suction pipe 2350 as illustrated in FIG. 6. The photoresist introduced into the suction pipe 2350 is detected by the first sensor 2353, and the detection result is transmitted to the controller 30. The controller 30 receives a detection signal from the first sensor 2353 and closes the suction pipe valve 2351 to prevent the photoresist from being introduced into the ejector 2100.

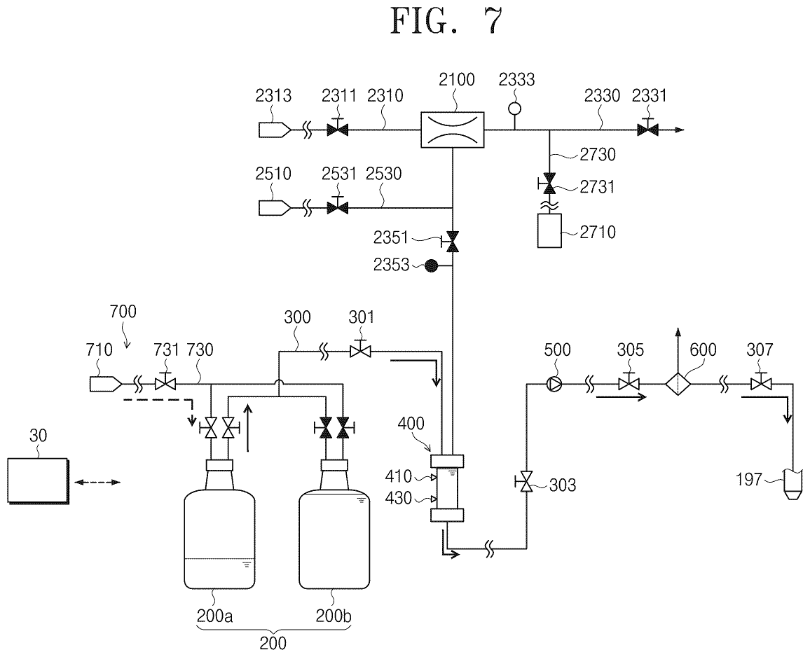

The suction pipe valve 2351 is closed to stop the formation of negative pressure in the inner space of the trap tank 400, and the photoresist in the trap tank 400 is supplied to the nozzle 197 by the flow pressure of the pump 500 as illustrated in FIG. 7, and the photoresist is fed from the bottle 200 to the trap tank 400 as much as the amount of photoresist fed from the trap tank 400 to the nozzle 197.

In FIGS. 5 to 7, the valves 303, 305, and 307 located on the downstream side of the trap tank 400 may be selectively opened and closed according to the operation of the pump 500, the supply of the treatment liquid to the substrate W, and the like.

When the suction pipe valve 2351 is not closed due to a failure or malfunction of the first sensor 2353 in FIG. 6, the photoresist is introduced into the ejector 2100 and then flows into the outlet pipe 2330, as illustrated in FIG. 8. Some of the photoresists introduced into the ejector 2100 may remain in or be deposited in the ejector 2100. In this case, the second sensor 2333 detects the photoresist introduced into the ejector 2100.

Referring to FIGS. 9 and 10, when the controller 30 receives a signal indicating that the photoresist has been introduced into the ejector 2100 from the second sensor 2333, the controller 30 closes the inlet pipe valve 2311, the outlet pipe valve 2331, and the suction pipe valve 2351 and opens the sampling pipe valve 2731 and the cleaning liquid supply pipe valve 2531. The photoresist introduced into the ejector 2100 flows into the sampling device 2710 through the sampling pipe 2730, and the sampling device 2710 detects the amount of photoresist introduced into the ejector 2100.

The controller 30 determines the flow rate of the cleaning liquid to be supplied to the ejector 2100 according to the amount of photoresist detected by the sampling device 2710, and supplies the cleaning liquid to the ejector 2100 through the cleaning liquid supply unit 2500 as much as the determined flow rate of the cleaning liquid.

After the cleaning liquid is supplied to the ejector 2100, the sampling device 2710 detects the amount of photoresist remaining in the ejector 2100 again. When the amount of photoresist detected by the sampling device 2710 is less than the set amount, cleaning is terminated, and when the amount of photoresist detected by the sampling device 2710 is greater than the set amount, the flow rate of the cleaning liquid is determined according to the amount of photoresist detected, and then the cleaning liquid with the determined flow rate is supplied to the ejector 2100.

The controller 30 feedback controls the sampling unit 2700 and the cleaning liquid supply unit 2500 to supply the cleaning liquid to the ejector 2100 until the amount of photoresist detected by the sampling device 2710 is less than or equal to a set amount.

The cleaning liquid sequentially flows through the suction pipe 2350, the ejector 2100, and the outlet pipe 2330 to remove the introduced photoresist to prevent solidification of the photoresist.

Since the flow rate of the cleaning liquid supplied to the ejector 2100 according to the exemplary embodiment of the present invention is determined in direct proportion to the amount of photoresist detected by the sampling device 2710, the cleaning liquid is not unnecessarily wasted and the ejector 2100 may be efficiently cleaned.

In FIGS. 8 to 9, the photoresist in the trap tank 400 is supplied to the nozzle 197 by the flow pressure of the pump 500. In addition, in FIG. 9, the photoresist is fed from the bottle 200 to the trap tank 400 as much as the amount of photoresist fed from the trap tank 400 to the nozzle 197. In FIGS. 8 to 9, the valves 303, 305, and 307 located on the downstream side of the trap tank 400 may be selectively opened and closed according to the operation of the pump 500, the supply of the treatment liquid to the substrate W, and the like.

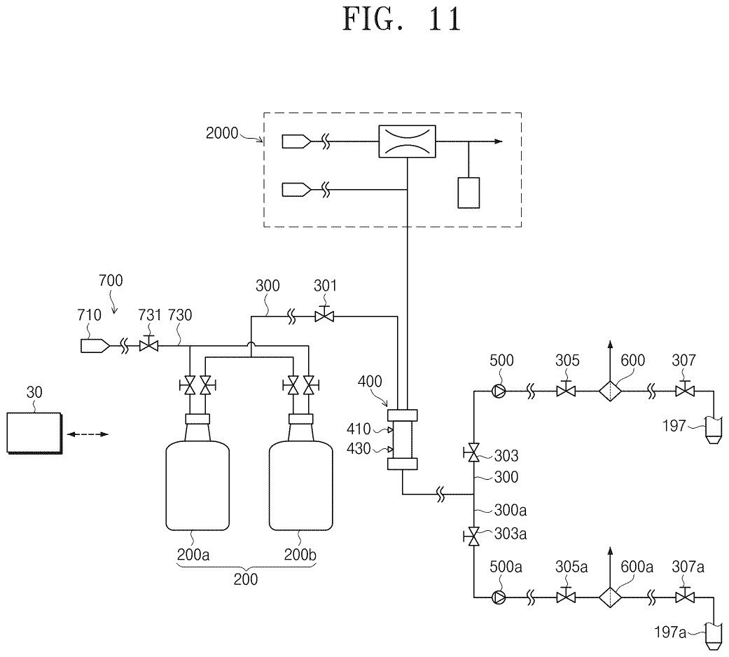

In the above-described exemplary embodiment of FIG. 2, the case where one nozzle 197 is connected to the liquid supply pipe 300 to receive the liquid from the trap tank 400 has been described as an example. However, the present invention is not limited thereto, and the liquid supply pipe 300 may be branched from a downstream side of the trap tank 400 to be connected to the plurality of nozzles 197 and 197a as illustrated in FIG. 11. The branched liquid supply pipe 300a may include a pump 500a, a filter 600a, and valves 303a, 305a, and 307a, which perform the same functions as the pump 500, the filter 600, and the valves 303, 305, and 307 installed in the liquid supply pipe 300.

In the above-described exemplary embodiment of FIG. 2, the present invention has been described based on the case where the plurality of bottles 200 is provided as an example. However, the present invention is not limited thereto, and a single bottle 200 may be provided to store a liquid.

In the above-described exemplary embodiment of FIG. 6, it has been described that when a photoresist is detected by the first sensor 2353, the suction pipe valve 2351 is closed. However, the present invention is not limited thereto, and when a photoresist is detected by the first water level detection sensor 410 provided on the upper end side of the trap tank 400, the suction pipe valve 2351 may be controlled to be closed.

In the above-described exemplary embodiments, the case in which the photoresist temporarily stored in the trap tank 400 is supplied to the nozzle 197 through the flow pressure of the pump 500 has been described as an example. However, unlike this, a bezel unit that provides suction pressure between the trap tank 400 and the pump 500 may be installed in the liquid supply pipe 300. The bezel unit may suck the photoresist in the trap tank 400 and transmit the photoresist to the pump 500.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a treating unit for processing a substrate; and
a liquid supply unit for supplying a treatment liquid to the substrate disposed in the treating unit,
wherein the liquid supply unit includes:
a bottle for storing the treatment liquid;
a liquid supply line for supplying the treatment liquid from the bottle to the treating unit;
a trap tank installed in the liquid supply line and temporarily storing the treatment liquid;
a negative pressure forming unit for forming a negative pressure inside the trap tank to feed the treatment liquid in the bottle to the trap tank;
a cleaning liquid supply unit for supplying a cleaning liquid to the negative pressure forming unit; and
a sampling unit for detecting the amount of the treatment liquid introduced into the negative pressure forming unit.

2. The apparatus of claim 1, wherein the negative pressure forming unit includes:
an ejector;
an inlet pipe for supplying gas to the ejector;
an outlet pipe for discharging the gas that has passed through the ejector; and
a suction pipe connecting the ejector and the trap tank, and
the sampling unit includes:
a sampling pipe branched from the outlet pipe; and
a sampling device for detecting the amount of the treatment liquid introduced through the sampling pipe.

3. The apparatus of claim 2, wherein the cleaning liquid supply unit includes a cleaning liquid supply pipe connected to the suction pipe.

4. The apparatus of claim 2, wherein the sampling device is an ultraviolet-visible spectrophotometer (UV-Vis spectrophotometer).

5. The apparatus of claim 3, wherein a first opening/closing valve is installed in the outlet pipe, and
a point at which the sampling pipe is branched from the outlet pipe is located between the ejector and the first opening/closing valve.

6. The apparatus of claim 5, wherein a second opening/closing valve is installed in the inlet pipe,
a third opening/closing valve is installed in the sampling pipe,
a fourth opening/closing valve is installed in the suction pipe,
a fifth opening/closing valve is installed in the cleaning liquid supply pipe, and
the cleaning liquid supply pipe is connected to the suction pipe between the ejector and the fourth opening/closing valve.

7. The apparatus of claim 6, further comprising:
a controller for controlling the liquid supply unit,
wherein a sensor for detecting whether the treatment liquid is introduced is further installed in the outlet pipe, and
when the sensor detects that the treatment liquid has been introduced into the outlet pipe, the controller controls the liquid supply unit to close the first opening/closing valve, the second opening/closing valve, and the fourth opening/closing valve, and open the third opening/closing valve and the fifth opening/closing valve.

8. The apparatus of claim 1, further comprising:
a controller for controlling the liquid supply unit,
wherein the controller determines the amount of cleaning liquid supplied to the negative pressure forming unit according to the amount of the treatment liquid detected by the sampling unit.

9. The apparatus of claim 8, wherein the controller detects the amount of the treatment liquid remaining in the negative pressure forming unit through the sampling unit again after the cleaning liquid is supplied to the negative pressure forming unit, and feedback-controls the sampling unit and the cleaning liquid supply unit to supply the cleaning liquid to the negative pressure forming unit until the amount of the treatment liquid detected by the sampling unit becomes less than or equal to a set amount.

10. The apparatus of claim 1, wherein the treatment liquid is a photoresist.

11. The apparatus of claim 1, wherein the cleaning liquid is a thinner.

12.-20. (canceled)
